(19) United States
(12) Patent Application Publication
(10) Pub. No.: US 2011/0316117 A1
(43) Pub. Date: Dec. 29, 2011

(54) DIE PACKAGE AND A METHOD FOR MANUFACTURING THE DIE PACKAGE

(75) Inventors: Vaidyanathan Kripesh, Singapore (SG); Navas Khan Oratti Kalandar, Singapore (SG); Srinivasa Rao Vempati, Singapore (SG); Aditya Kumar, Singapore (SG); Soon Wee Ho, Singapore (SG); Yak Long Samuel Lim, Singapore (SG); Gaurav Sharma, Singapore (SG); Wen Sheng Vincent Lee, Singapore (SG)

(73) Assignee: AGENCY FOR SCIENCE, TECHNOLOGY AND RESEARCH

(21) Appl. No.: 12/673,503

(22) PCT Filed: Aug. 12, 2008
(86) PCT No.: PCT/SG2008/000297

§ 371 Date: Dec. 30, 2010

Related U.S. Application Data
(60) Provisional application No. 60/955,795, filed on Aug. 14, 2007.

(30) Foreign Application Priority Data
Aug. 16, 2007 (JP) 2007-212505

(51) Int. Cl. H01L 29/02; H01L 23/498; H01L 23/552; H01L 21/50; H01L 23/48

(52) U.S. Cl. 257/531; 438/107; 257/771; 257/772; 257/659; 257/532; 257/536; 257/737; 257/E21.499; 257/E23.01; 257/E23.114; 257/E29.002; 257/E23.068

(57) ABSTRACT

A die package and a method for manufacturing the die package are provided. The die package includes a second die arranged above a first die, the first die comprising an interconnect region on a surface facing the second die, wherein the second die is arranged laterally next to the interconnect region of the first die; a first package-internal free-standing interconnect structure disposed above the interconnect region of the first die; a second package-internal free-standing interconnect structure disposed above an interconnect region of the second die, the interconnect region of the second die being on a surface of the second die facing away from the first die; and package material formed partially around the first package-internal free-standing interconnect structure and the second package-internal free-standing interconnect structure such that a connecting portion of the first package-internal free-standing interconnect structure and a connecting portion of the second package-internal free-standing interconnect structure remains uncovered to be electrically connected to a package-external interconnect structure.

### TECHNICAL FIELD

Embodiments relate generally to a die package and a method for manufacturing the die package.

### BACKGROUND

The primary trend in electronics industry is product miniaturization. Both design and manufacturing engineers are looking for ways to make electronic products lighter, smaller, less expensive, and at the same time faster, more efficient, more reliable, more user-friendly, and more functional. Today, electronic products such as cellular phones, personal and sub-notebook computers, pagers, Personal Computer Memory Card International Association (PCMCIA) cards, camcorders, palmtop organizers, telecommunications equipments, and automotive components are being made more and more compact.

With silicon chips integrating more functionality as per Moore's Law, the electronics industry is being challenged to integrate and shrink the packaging. Chips First or Embedded Chip packaging is one way to overcome the recent packaging integration challenges. Packaging researchers have worked on embedded packaging and developed a new way of embedding the chip. Plastic ball grid array (PBGA) packages have replaced the lead frame based peripheral array packages. In PBGA packages, a die is electrically connected to a circuit board (PCB) substrate by wire bonding or flip chip technology before covering with a molding compound. Embedded wafer level packaging eliminates the need of using the PCB substrate and wire bonding or flip-chip bumps to establish electrical connections. By removing the PCB substrate, packaging cost is reduced and electrical performances are improved.

However, most of the known technologies focused only on two-dimensions (2D) embedding. Further, there is no known technology for embedding passives and other structures required for system in package (SiP) integration in a cost effective manner.

In one conventional method, embedding singulated die based on PCB technology has been adopted. The singulated die is first attached onto a copper (Cu) base plate in a cavity of a PCB substrate and the subsequent Cu rewiring and vias are then built up on top of the active side based on the PCB technology. Finally, solder balls are formed on top of the Cu pads for electrical interconnection.

Another conventional method is based on wafer level processing. The fabrication method involves attaching singulated dies with active top side down onto a thermo-sensitive adhesive material coupled to a carrier plate. A wafer molding process is then used to encapsulate the attached dies on the carrier plate. The carrier plate is then separated and the dies are housed in a mold compound, forming a reconstituted wafer. A redistribution layer can be formed on the reconstituted wafer using conventional lithographic process. Solder bumps can also be formed on the wafer level prior to singulation.

However, fine feature size may be a challenge for the above-mentioned technologies, and there may be problems in the supply chain for the conventional technologies. Further, the conventional technologies focused on single die or 2D integration only. The conventional technologies are not implementable for Microelectromechanical systems (MEMS), photonics and other applications.

Since current and future innovations in packaging format will be critical to miniaturizing electronic products, there is a need to provide a new packaging method which partially overcomes at least one of the above-mentioned problems. It will also be desirable to provide a new packaging method for embedding actives and passives that will help to enable future advances in chip speed and circuit functionality.

### SUMMARY

In an embodiment, there is provided a method for manufacturing a die package, the method including: arranging a second die above a first die, the first die including an interconnect region on a surface facing the second die, wherein the second die is arranged laterally next to the interconnect region of the first die; forming a first package-internal free-standing interconnect structure on or above the interconnect region of the first die; forming a second package-internal free-standing interconnect structure on or above an interconnect region of the second die, the interconnect region of the second die being on a surface of the second die facing away from the first die; and forming package material partially around the first package-internal free-standing interconnect structure and the second package-internal free-standing interconnect structure such that a connecting portion of the first package-internal free-standing interconnect structure and a connecting portion of the second package-internal free-standing interconnect structure remains uncovered to be electrically connected to a package-external interconnect structure.

In another embodiment, there is provided a die package including: a second die arranged above a first die, the first die including an interconnect region on a surface facing the second die, wherein the second die is arranged laterally next to the interconnect region of the first die; a first package-internal free-standing interconnect structure disposed above the interconnect region of the first die; a second package-internal free-standing interconnect structure disposed above an interconnect region of the second die, the interconnect region of the second die being on a surface of the second die facing away from the first die; and package material formed partially around the first package-internal free-standing interconnect structure and the second package-internal free-standing interconnect structure such that a connecting portion of the first package-internal free-standing interconnect structure and a connecting portion of the second package-internal free-standing interconnect structure remains uncovered to be electrically connected to a package-external interconnect structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the various embodiments. In the following description, various embodiments are described with reference to the following drawings, in which:

FIG. 1 shows a schematic diagram of a die package structure in accordance with an embodiment.

FIG. 2 shows a schematic diagram of an overall process flow for manufacturing the die package at a wafer level.

FIGS. 3a to 3j show schematic diagrams of a process for manufacturing the die package at the wafer level.

FIG. 4 shows a flowchart of the process for manufacturing the die package at the wafer level.

FIG. 5a shows a schematic diagram of chip passives embedded within the package material of the die package.

FIG. 5b shows a schematic diagram of chip passives embedded on the package material of the die package.

FIG. 6a shows a schematic diagram of chip passives and a thin film passive embedded within the package material of the die package.

FIG. 6b shows a schematic diagram of chip passives embedded on the package material of the die package and a thin film passive embedded within the package material of the die package.

FIG. 7 shows a schematic diagram of an antenna embedded within the package material of the die package.

FIG. 8 shows a schematic diagram of an electromagnetic field shield embedded within the package material of the die package.

FIG. 9 shows a schematic diagram of a heat spreader embedded on the package material of the die package.

FIG. 10 shows a schematic diagram of a single die, a multi-die stack and chip passives embedded within the package material of the die package.

FIG. 11 shows a schematic diagram of a die package for a mobile application.

FIG. 12 shows a schematic diagram of a die package for a memory application.

FIG. 13 shows a schematic diagram of a die package for a processor application.

FIG. 14 shows a schematic diagram of a die package for a Microelectromechanical system (MEMS) application.

FIG. 15 shows a schematic diagram of a die package for an optical application.

FIG. 16 shows a schematic diagram of a die package for a radio frequency (RF) application.

FIGS. 17a and 17b show schematic diagrams of a die package having dies of the same size.

### DETAILED DESCRIPTION

Exemplary embodiments of a die package are described in detail below with reference to the accompanying figures. It will be appreciated that the exemplary embodiments described below can be modified in various aspects without changing the essence of the invention.

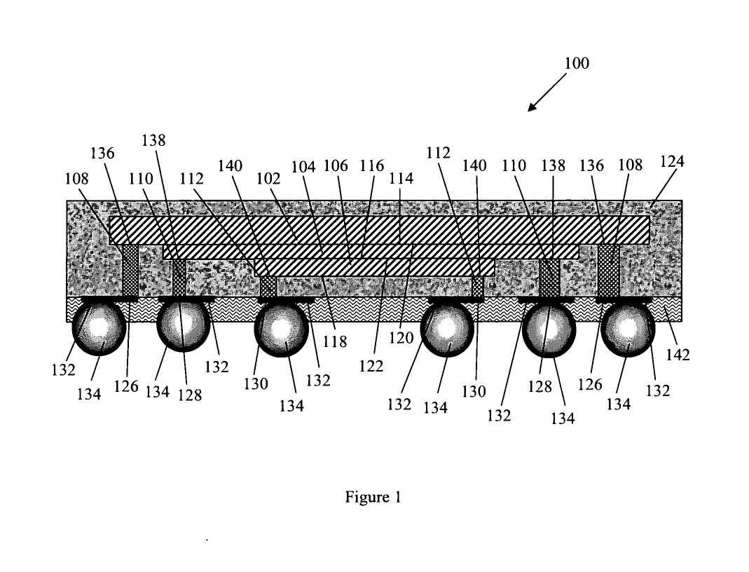

FIG. 1 shows a schematic diagram of a die package 100 manufactured in accordance with an embodiment. The die package 100 may include a plurality of dies (e.g. three dies) 102, 104, 106 stacked above one another of the die stack. A first die 102 which is arranged on the opposite side with respect to solder bumps 134 to be formed in a later process, as will be described in more detail below, is the one with the largest size of the plurality of dies and a third die 106 which is arranged on the side of the die stack facing the solder bumps 134 to be formed, is the one with the smallest size. Each die 102, 104, 106 may include one or a plurality of interconnect structures (e.g. two interconnect structures) 108, 110, 112, respectively. The interconnect structures 108, 110, 112 may be disposed on opposite ends of a main processing surface 114, 116, 118 of the dies 102, 104, 106, respectively. The interconnect structures 108, 110, 112 may be arranged in respective interconnect regions 136, 138, 140 on the main processing surface 114, 116, 118 of the respective die 102, 104, 106. The interconnect structures 108, 110, 112 may be pillar-shaped as one example of a free-standing interconnect structure 108, 110, 112, and may be made of an electrically conductive material such as e.g. metal such as e.g. aluminum or copper or alloy such as solders. A second die 104 is disposed laterally between the interconnect structures 108 of the first die 102 such that a back side surface 120 of the second die 104 is facing the main processing surface 114 of the first die 102. Similarly, the third die 106 with the smallest size within the dies of the die stack is disposed laterally between the interconnect structures 110 of the second die 104 such that a back side surface 122 of the third die 106 is facing the main processing surface 116 of the second die 104.

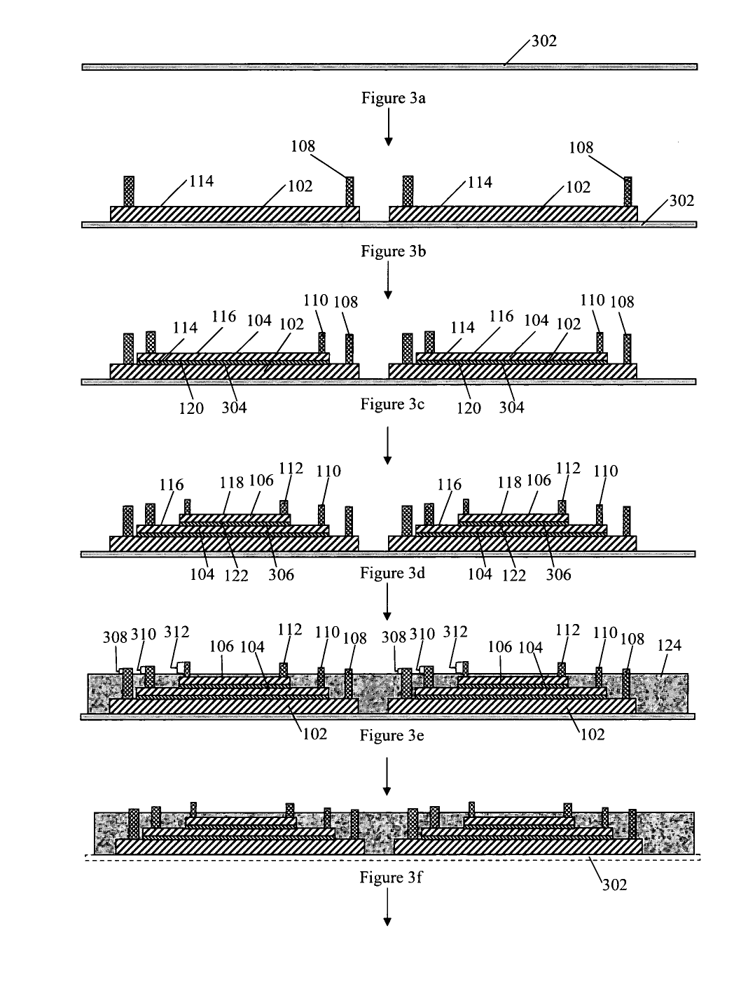

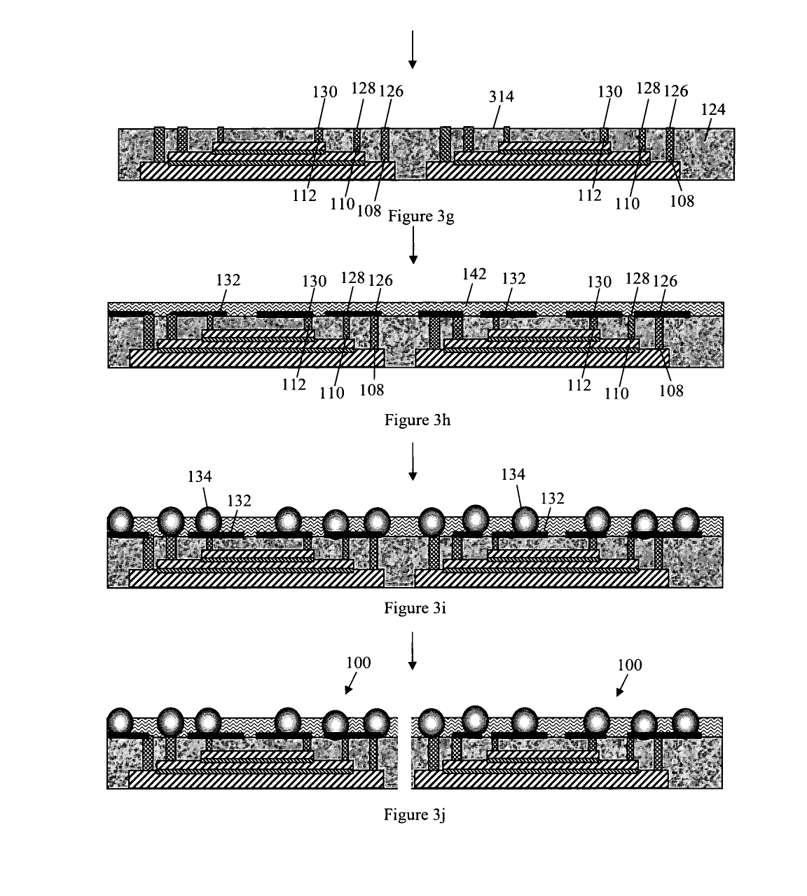

In an embodiment as described below in FIG. 3, for mechanical stability and bonding purposes, the main processing side 114 of first die 102 may be attached to the back side surface 120 of the second die 104 with an attachment layer (which can also be referred to as a bonding layer) (not shown), if required. Similarly, the main processing side 116 of the second die 104 may be attached to the back side surface 122 of the third die 106 with an attachment layer (which can also be referred to as a bonding layer) (not shown), if required.

Package material such as e.g. ceramic, plastic, epoxy, 124 may be formed around the dies 102, 104, 106 and the respective interconnect structures 108, 110, 112 such that respective connecting portions 126, 128, 130 of the interconnect structures 108, 110, 112 are not covered by the package material 124. A redistribution layer 132 may be formed on the connecting portions 126, 128, 130 of the interconnect structures 108, 110, 112. Metallic interconnects, e.g. in the form of solder bumps 134 may be formed on the redistribution layer 132. An insulating dielectric layer 142 may be formed on the redistribution layer 132. In order to form a multilayer redistribution layer, a multilayer dielectric layer 142 may be used for isolation and redistribution.

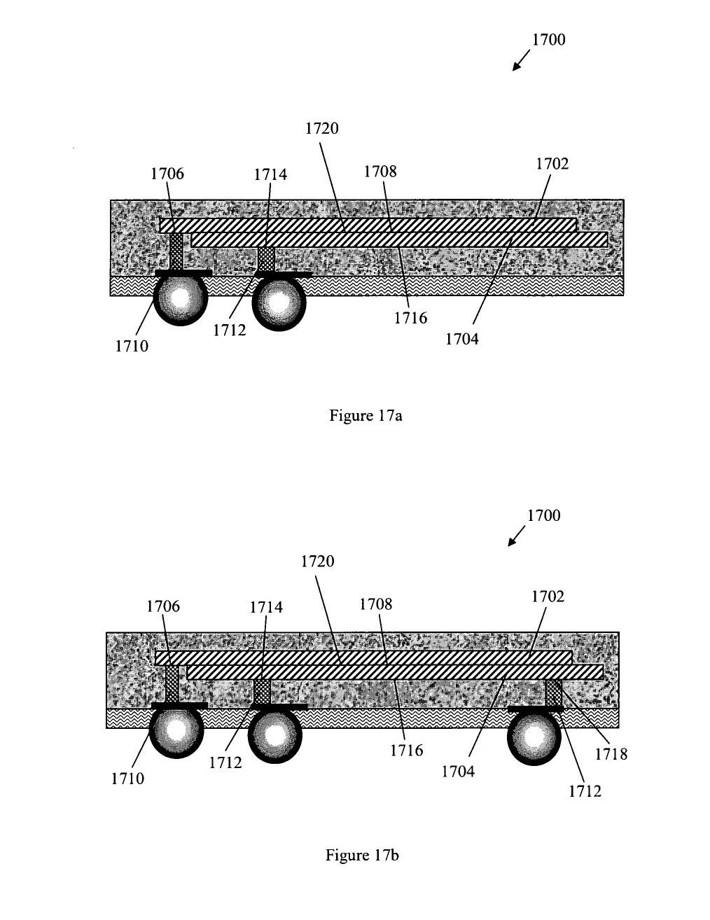

The structure of the die package 100 is not limited to the embodiment as shown in FIG. 1. In alternative embodiments, the dies may be of the same size. FIGS. 17a and 17b show schematic diagrams of a die package 1700 having dies of the same size. The die package 1700 may include a plurality of dies (e.g. two dies) 1702, 1704, of the same size stacked above one another of the die stack. A first die may include an interconnect region 1706 on a main processing surface 1708 facing a second die 1704. The second die 1704 may be arranged laterally next to the interconnect region 1706 of the first die 1702 and on the main processing surface 1708 of the first die 1702. A first interconnect structure 1710 may be disposed on the interconnect region 1706 of the first die 1702. A second interconnect structure 1712 may be disposed above an interconnect region 1714 on a main processing surface 1716 of the second die 1704. The interconnect structures 1710, 1712 may be pillar-shaped as one example of a free-standing interconnect structure 1710, 1712, and may be made of an electrically conductive material such as e.g. metal such as e.g. aluminum or copper or alloy such as solders.

FIG. 17b shows that the second interconnect structure 1712 may be further disposed above a further interconnect region 1718 on the main processing surface 1716 of the second die 1704. The interconnect region 1714 and the further interconnect region 1718 of the second die 1704 may be on two opposite ends of the main processing surface 1716 of the second die 1704 facing away from the first die 1702.

In the embodiment as described below in FIG. 3, for mechanical stability and bonding purposes, the main processing side 1708 of the first die 1702 may be attached to a back side surface 1720 of the second die 1704 with an attachment layer (which can also be referred to as a bonding layer) (not shown), if required.

The number of dies and the number of interconnect structures for each die can be different in different embodiments. Further, the shapes of the interconnect structures can be different in other embodiments. The interconnect structures can also be made of other electrically conductive materials.

A method for manufacturing the die package at a wafer level is described in the following. The method described below is used for manufacturing the die package 100 as shown in FIG. 1. The methods of manufacturing different embodiments of the die package will be apparent from the method described below.

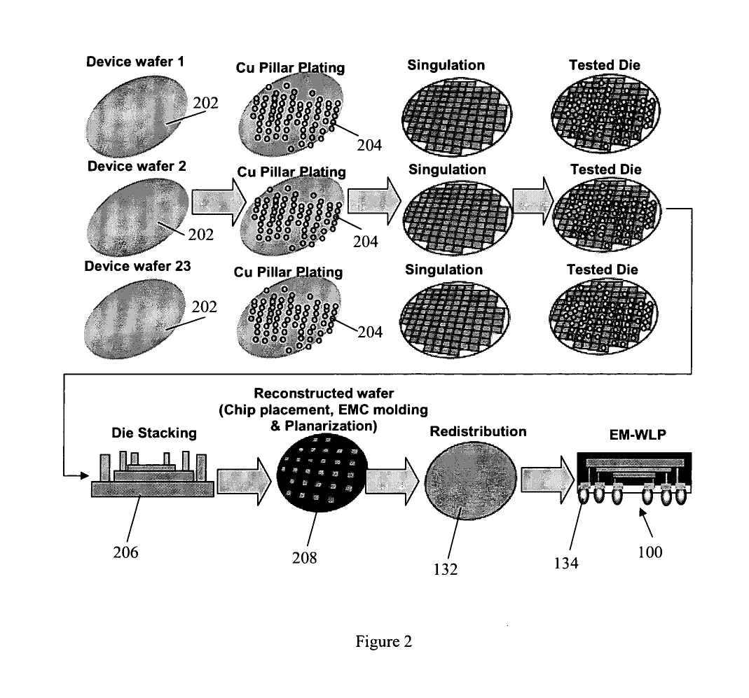

FIG. 2 shows a schematic diagram of a process for manufacturing the die package 100 at a wafer level. Firstly, a plurality of device wafers 202 may be tested and the dies of working condition of the device wafers 202 are identified and will be further processed. Secondly, the device wafers 202 may be plated with interconnect structures 204 on the input/output (I/O) pads of the dies, which I/O pads may be one example implementation of an interconnect region. The height of the interconnect structures 204 of each die is calculated based on the number of dies and the thickness of the dies to be stacked above it. The interconnect structures 204 with pre-designed heights allows stacking of the dies. Thirdly, the device wafers 202 may be diced into individual dies. The dies of working condition from different device wafers 202 may be selected and stacked one above the other using an as such conventional die attach and stacking process to form a die stack 206. The die stacks 206 may be attached to a support wafer or tape and reconstructed to a wafer form 208 for further processing, e.g. molding, planarization, forming a redistribution layer 132 and metallic interconnects in the form of solder bumps 134, before the die package 100 is completed. The detailed process for manufacturing the die package 100 is described in the following.

FIGS. 3a to 3j show schematic diagrams of the process for manufacturing the die package 100 at the wafer level. After the device wafers 202 are diced into individual dies, the dies of good working condition are selected and are attached to a support wafer or tape for reconstruction to a wafer form. A person skilled in the art will be able to determine the dies of good working condition by e.g. testing the dies to determine if the dies have certain characteristics, e.g. long operating life, etc.

FIG. 3a shows a schematic diagram of a tape 302 used for reconstruction to the wafer form. The tape 302 is one which can withstand high temperatures, e.g. in the range from about 100° C. to about 210° C. FIG. 3b shows that a plurality of first dies 102 is disposed on the tape 302. Each first die 102 may include a plurality of, e.g. two interconnect structures 108 as described above. The interconnect structures 108 of each first die 102 may be disposed on two opposite ends of a main processing surface 114 of each first die 102.

FIG. 3c shows that a second die 104 is then disposed above the respective first die 102 and laterally between the interconnect structures 108 of the respective first die 102. Each second die 104 may include a plurality of, e.g. two interconnect structures 110. The interconnect structures 110 of each second die 104 may be disposed on two opposite ends of a main processing surface 116 of each second die 104 facing away from the respective first die 102. Referring back to FIGS. 1, 17a and 17b, for mechanical stability and bonding purposes, a bonding layer 304 may be disposed between the main processing surface 114 of the first die 102 facing the second die 104 and a back side surface 120 of the second die 104 facing the first die 102.

FIG. 3d shows that a third die 106 may be disposed above the respective second die 104 and laterally between the interconnect structures 110 of the respective second die 104. Each third die 106 may include a plurality of, e.g. two interconnect structures 112. The interconnect structures 112 of each third die 106 may be disposed on two opposite ends of a main processing surface 118 of each third die 106 facing away from the respective second die 104. Referring back to FIGS. 1, 17a and 17b, for mechanical stability and bonding purposes, a bonding layer 306 may be disposed between the main processing surface 116 of the second die 104 facing the third die 106 and a back side surface 122 of the third die 106 facing the second die 104.

FIG. 3e shows that a package material 124 is formed around the dies 102, 104, 106 and the respective interconnect structures 108, 110, 112 such that upper regions 308, 310, 312 of the interconnect structures 108, 110, 112 remain uncovered from the package material. FIG. 3f shows that then the tape 302 may be removed. Post mold cure can be carried out to minimize wafer warpage. FIG. 3g shows that a top surface 308 of the package material 124 is grinded using mechanical grinding or a single point tool shaving process to planarize the top surface 314 and/or to expose the respective connecting portions 126, 128, 130 of the interconnect structures 108, 110, 112 which may be covered by the package material 124.

FIG. 3h shows that a redistribution layer 132 may then be formed on the respective connecting portions 126, 128, 130 of the interconnect structures 108, 110, 112. Using the redistribution layer 132 enables the removal of wire bonds or flip chip interconnects. The redistribution layer 132 interconnects the I/O pads of the dies 102, 104, 106. An insulating dielectric layer 142 may be formed on the redistribution layer 132. In order to form a multilayer redistribution layer, a multilayer dielectric layer 142 may be used for isolation and redistribution. FIG. 3i shows that metallic interconnects in the form of solder balls 134 are formed on the redistribution layer 132. FIG. 3j shows that singulation may then be carried out and the die package 100 as shown in FIG. 1 is formed.

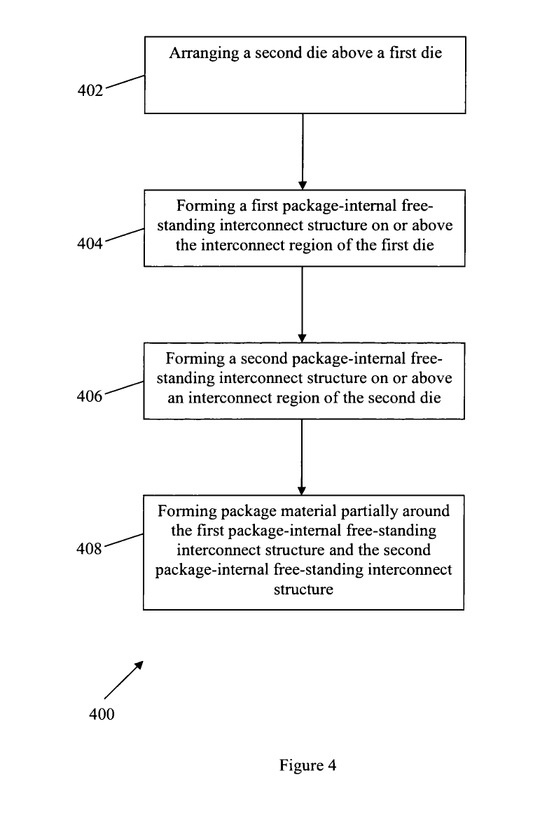

FIG. 4 shows a flowchart 400 of the process for manufacturing the die package at the wafer level. At 402, a second die is arranged above a first die. The first die may include an interconnect region on a surface facing the second die and the second die is arranged laterally next to the interconnect region of the first die. At 404, a first package-internal free-standing interconnect structure is formed on or above the interconnect region of the first die. At 406, a second package-internal free-standing interconnect structure is formed on or above an interconnect region of the second die. The interconnect region of the second die is on a surface of the second die facing away from the first die. At 408, package material is formed partially around the first package-internal free-standing interconnect structure and the second package-internal free-standing interconnect structure such that a connecting portion of the first package-internal free-standing interconnect structure and a connecting portion of the second package-internal free-standing interconnect structure remains uncovered to be electrically connected to a package-external interconnect structure.

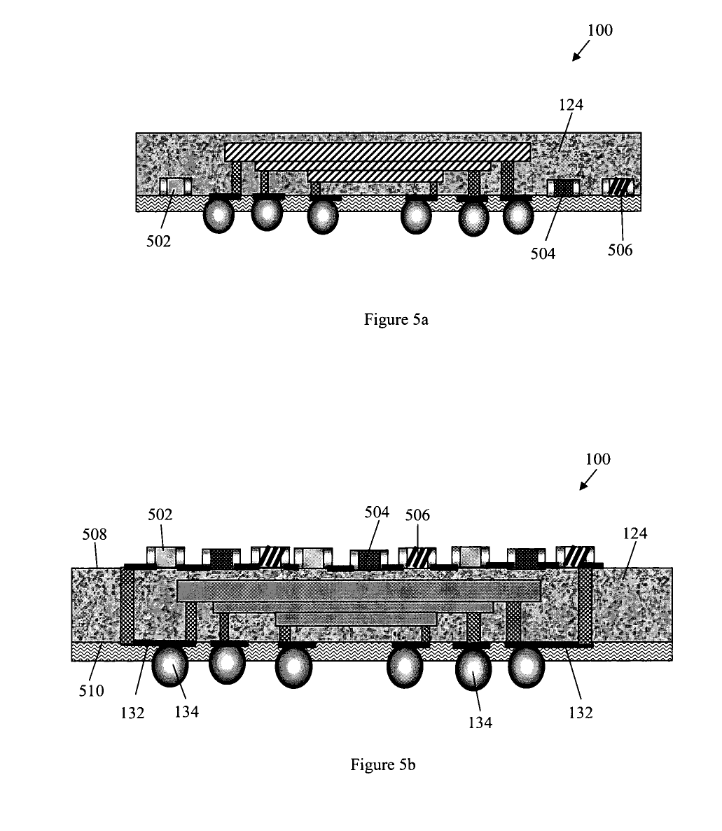

There are different variations of the die package 100 manufactured by the method described above. One variation of the die package 100 is embedding chip passives within the package material 124 of the die package 100. FIG. 5a shows a schematic diagram of chip passives embedded within the package material 124 of the die package 100. The chip passives include but are not limited to a capacitor 502, a resistor 504 and an inductor 506.

FIG. 5b shows a schematic diagram of the chip passives embedded on the package material 124 of the die package 100. The chip passives including but not limited to a capacitor 502, a resistor 504 and an inductor 506 are embedded on a surface 508 of the package material 124, which is opposite to the surface 510 having the redistribution layer 132 and the solder bumps 134.

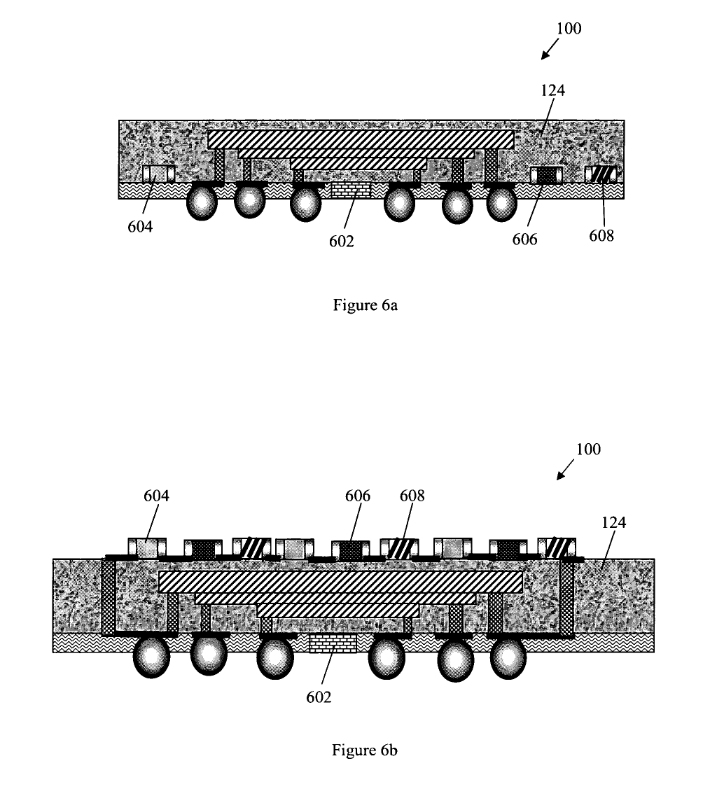

Another variation of the die package 100 is embedding thin film passives using wafer level redistribution layer processes as described above. FIG. 6a shows a schematic diagram of chip passives and a thin film passive 602 embedded within the package material 124 of the die package 100. The chip passives include but are not limited to a capacitor 604, a resistor 606, an inductor 608 and an integrated device having any one or more of a group including the capacitor 604, the resistor 606 and the inductor 608. FIG. 6b shows a schematic diagram of the chip passives embedded on the package material 124 of the die package 100 and the thin film passive 602 embedded within the package material 124 of the die package 100. The chip passives include but are not limited to the capacitor 604, the resistor 606, the inductor 608 and an integrated device having any one or more of a group including the capacitor 604, the resistor 606 and the inductor 608.

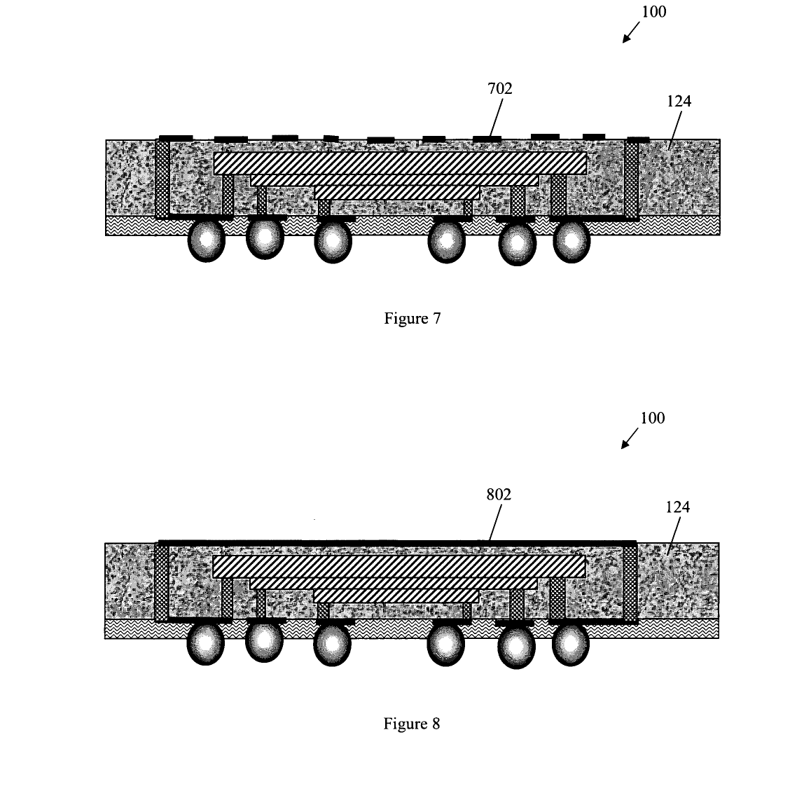

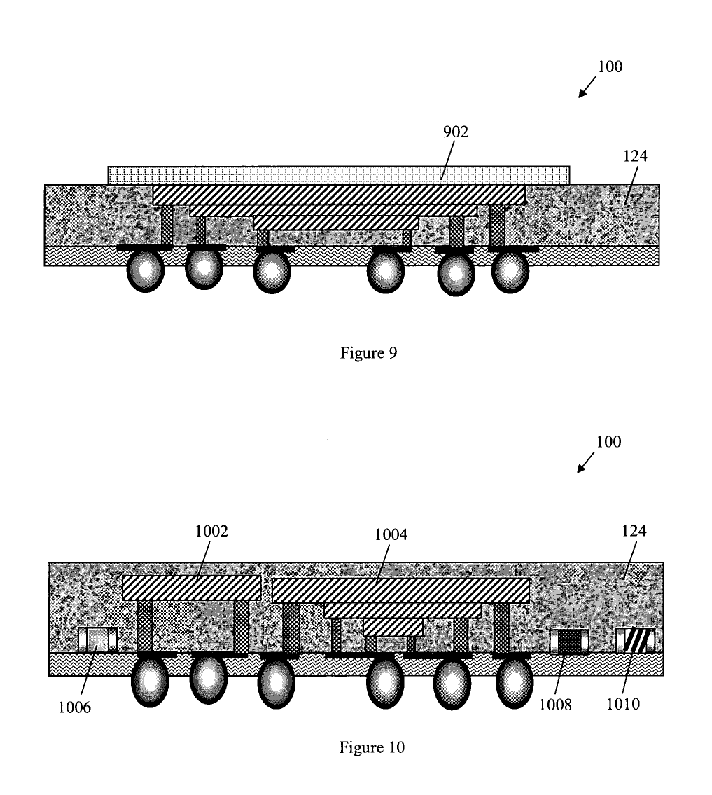

Other components including but not limited to heat spreaders, package antennas and electromagnetic interference (EMI) shields can also be embedded within the package material 124 of the die package 100. FIG. 7 shows a schematic diagram of an antenna 702 embedded within the package material 124 of the die package 100. FIG. 8 shows a schematic diagram of an EMI shield 802 embedded within the package material 124 of the die package 100. FIG. 9 shows a schematic diagram of a heat spreader 902 embedded on the package material 124 of the die package 100.

In addition, the die package 100 in an embodiment allows multiple die stacking in two-dimension (2D) and three-dimension (3D) configurations. FIG. 10 shows a schematic diagram of a single die 1002, a multi-die stack 1004 and chip passives embedded within the package material 124 of the die package 100. The chip passives include but are not limited to a capacitor 1006, a resistor 1008 and an inductor 1010.

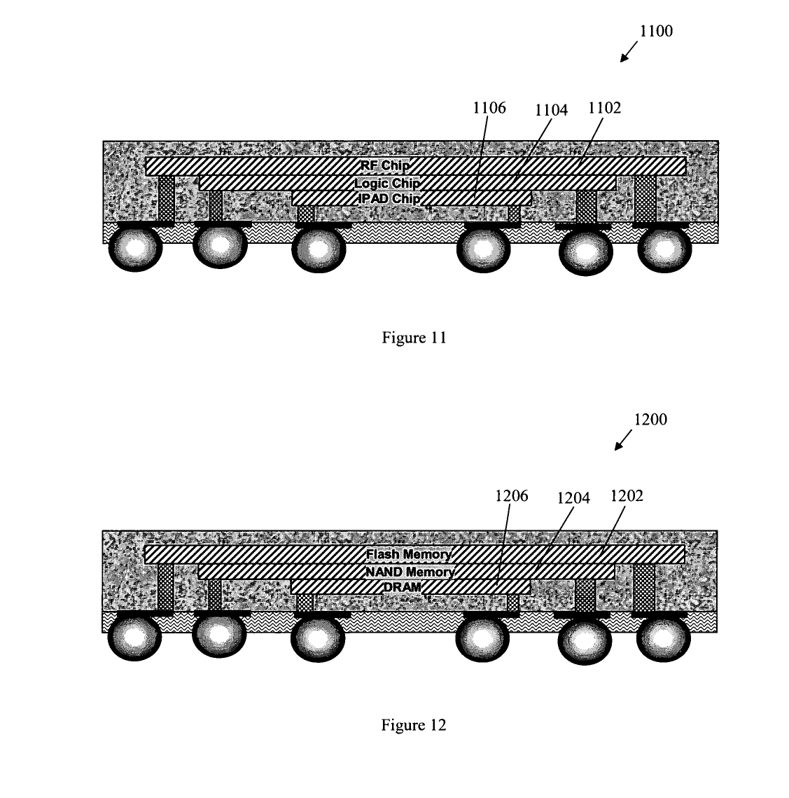

In addition, the die package 100 can be implemented in various applications including but not limited to mobile, memory, processor, microelectromechanical system (MEMS), optical and radio frequency (RF) applications. FIG. 11 shows a schematic diagram of a die package 1100 for a mobile application. The die package 1100 may include a radio frequency (RF) chip 1102, a logic chip 1104 and an integrated passive and active device (IPAD) chip 1106.

FIG. 12 shows a schematic diagram of a die package 1200 for a memory application. The die package 1200 may include a flash memory 1202, a NAND memory 1204 and a dynamic random access memory (DRAM) 1206.

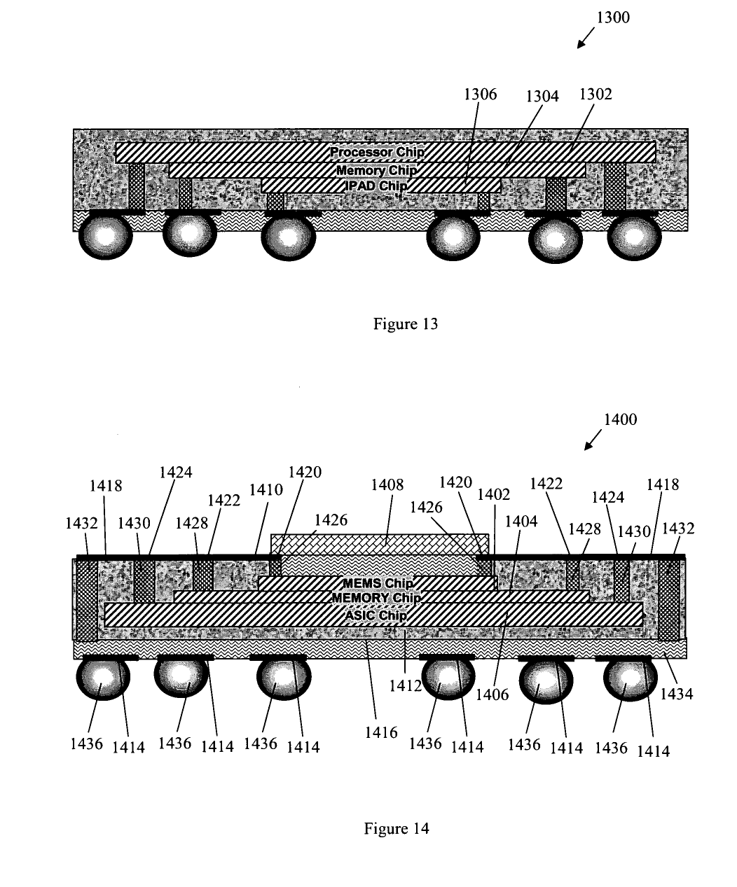

FIG. 13 shows a schematic diagram of a die package 1300 for a processor application. The die package 1300 may include a processor chip 1302, a memory chip 1304 and an IPAD chip 1306.

FIG. 14 shows a schematic diagram of a die package 1400 for a microelectromechanical system (MEMS) application. The die package 1400 may include a MEMS chip 1402, a memory chip 1404 and an application-specific integrated circuit (ASIC) chip 1406. The die package 1400 may further include a MEMS cap 1408 with a low temperature bonding. With the MEMS cap 1408 on a surface 1410 of a package material 1412, a redistribution layer 1414 may be formed on or above a back side surface 1416 of the package material 1412. The die package 1400 may include a conductive layer 1418 formed on respective connecting portions 1420, 1422, 1424 of interconnect structures 1426, 1428, 1430 of the MEMS chip 1402, the memory chip 1404 and the ASIC chip 1406. The conductive layer 1418 can be a redistribution layer.

The die package 1400 may include a plurality of interconnect structures (e.g. two interconnect structures) 1432. The interconnect structures 1432 may be disposed on two opposite ends of the die package 1400. The interconnect structures 1432 may extend from the conductive layer 1418 to the redistribution layer 1414. The MEMS chip 1402, the memory chip 1404 and the ASIC chip 1406 may be electrically connected to the redistribution layer 1414 via the conductive layer 1418 and the interconnect structures 1432.

An insulating dielectric layer 1434 may be formed on the redistribution layer 1414. Metallic interconnects in the form of solder balls 1436 are formed on the redistribution layer 1414.

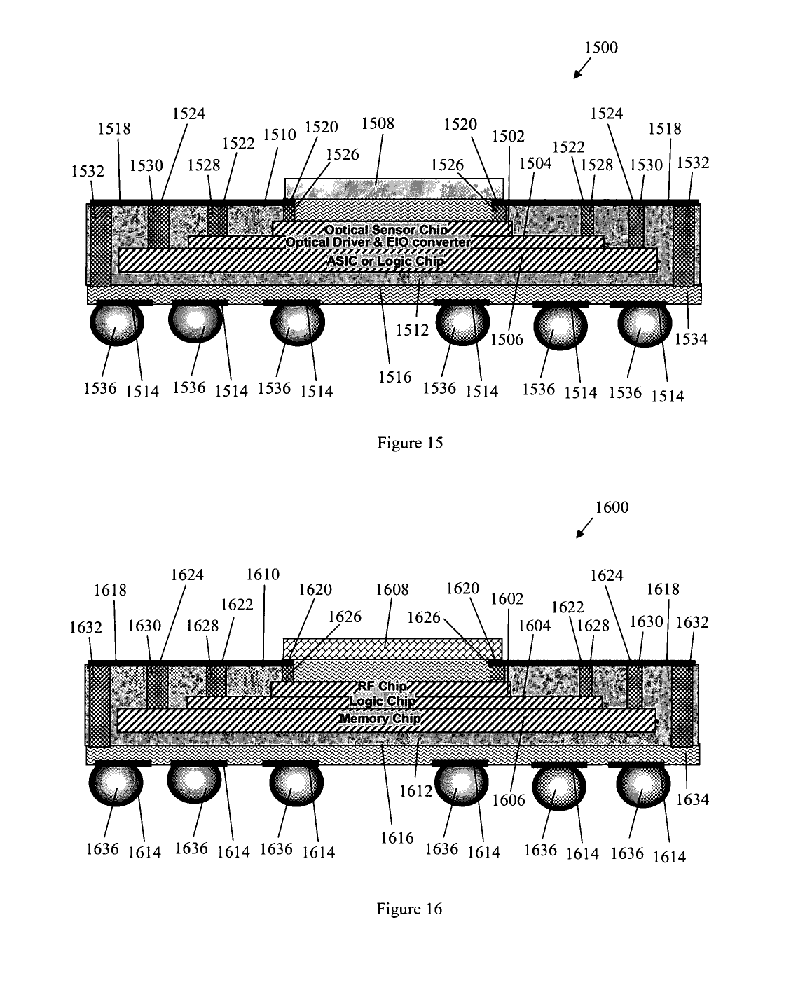

FIG. 15 shows a schematic diagram of a die package 1500 for an optical application. The die package 1500 may include an optical sensor chip 1502, an optical driver and electrical-optical (EIO) converter 1504 and an ASIC or logic chip 1506. The die package 1500 may further include a glass cap 1508 with a low temperature bonding. With the glass cap 1508 on a surface 1510 of a package material 1512, a redistribution layer 1514 may be formed on or above a back side surface 1516 of the package material 1512. The die package 1500 may include a conductive layer 1518 formed on respective connecting portions 1520, 1522, 1524 of interconnect structures 1526, 1528, 1530 of the optical sensor chip 1502, the optical driver and EIO converter 1504 and the ASIC or logic chip 1506. The conductive layer 1518 can be a redistribution layer.

The die package 1500 may include a plurality of interconnect structures (e.g. two interconnect structures) 1532. The interconnect structures 1532 may be disposed on two opposite ends of the die package 1500. The interconnect structures 1532 may extend from the conductive layer 1518 to the redistribution layer 1514. The optical sensor chip 1502, the optical driver and EIO converter 1504 and the ASIC or logic chip 1506 may be electrically connected to the redistribution layer 1514 via the conductive layer 1518 and the interconnect structures 1532.

An insulating dielectric layer 1534 may be formed on the redistribution layer 1514. Metallic interconnects in the form of solder balls 1536 may be formed on the redistribution layer 1514.

FIG. 16 shows a schematic diagram of a die package 1600 for a radio frequency (RF) application. The die package 1600 may include a RF chip 1602, a logic chip 1604 and a memory chip 1606. The die package 1600 may further include a Faraday cage 1608 for EMI shielding. With the Faraday cage 1608 on a surface 1610 of a package material 1612, a redistribution layer 1614 may be formed on or above a back side surface 1616 of the package material 1612. The die package 1600 may include a conductive layer 1618 formed on respective connecting portions 1620, 1622, 1624 of interconnect structures 1626, 1628, 1630 of the RF chip 1602, the logic chip 1604 and the memory chip 1606. The conductive layer 1618 can be a redistribution layer.

The die package 1600 may include a plurality of interconnect structures (e.g. two interconnect structures) 1632. The interconnect structures 1632 may be disposed on two opposite ends of the die package 1600. The interconnect structures 1632 may extend from the conductive layer 1618 to the redistribution layer 1614. The RF chip 1602, the logic chip 1604 and the memory chip 1606 may be electrically connected to the redistribution layer 1614 via the conductive layer 1618 and the interconnect structures 1632.

An insulating dielectric layer 1634 may be formed on the redistribution layer 1614. Metallic interconnects in the form of solder balls 1636 may be formed on the redistribution layer 1614.

The structure of the die package and the method of manufacturing the die package may enable a wafer level reconstruction of the wafer and conventional wafer level processing can be carried over it. The method of manufacturing the die package may achieve a higher level of dies and passives integration in a smaller footprint. The method also may allow both 2D and 3D integration of the dies. The method may be suitable for multi-die, stack die and single die embedding and for fine pitch features. A lower cost may be incurred due to the simpler design and fabrication processes. There is also flexibility with the processes and the materials used for manufacturing the die package. Further, wafer level testing can be more easily conducted using the interconnect structures.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method for manufacturing a die package, the method comprising:
arranging a second die above a first die, the first die comprising an interconnect region on a surface facing the second die, wherein the second die is arranged laterally next to the interconnect region of the first die;
forming a first package-internal free-standing interconnect structure on or above the interconnect region of the first die;
forming a second package-internal free-standing interconnect structure on or above an interconnect region of the second die, the interconnect region of the second die being on a surface of the second die facing away from the first die; and
forming package material partially around the first package-internal free-standing interconnect structure and the second package-internal free-standing interconnect structure such that a connecting portion of the first package-internal free-standing interconnect structure and a connecting portion of the second package-internal free-standing interconnect structure remains uncovered to be electrically connected to a package-external interconnect structure.

2.-24. (canceled)

25. A die package comprising:
a second die arranged above a first die, the first die comprising an interconnect region on a surface facing the second die, wherein the second die is arranged laterally next to the interconnect region of the first die;
a first package-internal free-standing interconnect structure disposed above the interconnect region of the first die;
a second package-internal free-standing interconnect structure disposed above an interconnect region of the second die, the interconnect region of the second die being on a surface of the second die facing away from the first die; and
package material formed partially around the first package-internal free-standing interconnect structure and the second package-internal free-standing interconnect structure such that a connecting portion of the first package-internal free-standing interconnect structure and a connecting portion of the second package-internal free-standing interconnect structure remains uncovered to be electrically connected to a package-external interconnect structure.

26. The die package as claimed in claim 25, wherein the first die and the second die have the same size.

27. The die package as claimed in claim 25, wherein the first package-internal free-standing interconnect structure is further disposed above a further interconnect region of the first die on the surface facing the second die.

28. The die package as claimed in claim 27, wherein the interconnect region and the further interconnect region of the first die are on two opposite ends of the surface facing the second die.

29. The die package as claimed in claim 25, wherein the second package-internal free-standing interconnect structure is further disposed above a further interconnect region of the second die on the surface facing away from the first die.

30. The die package as claimed in claim 29, wherein the interconnect region and the further interconnect region of the second die are on two opposite ends of the surface facing away from the first die.

31. The die package as claimed in claim 25, wherein the package-internal free-standing interconnect structures are pillar-shaped.

32. The die package as claimed in claim 25, wherein the package-internal free-standing interconnect structures are made of conductive material.

33. The die package as claimed in claim 32, wherein the conductive material comprises at least one metal.

34. The die package as claimed in claim 33, wherein the at least one metal comprises any one or more of a group consisting of copper, aluminum and alloy.

35. The die package as claimed in claim 34, wherein the alloy comprises solders.

36. The die package as claimed in claim 25, further comprising a bonding layer disposed between the surface of the first die facing the second die and a surface of the second die facing the first die.

37. The die package as claimed in claim 25, wherein a surface of the first die facing away from the second die is disposed above a support wafer before forming the package material.

38. The die package as claimed in claim 37, wherein the support wafer comprises a tape.

39. The die package as claimed in claim 25, further comprising one or more components disposed within or above the package material.

40. The die package as claimed in claim 39, wherein the components comprise any one or more of a group consisting of a single die, capacitor, resistor, inductor, chip passive, thin film passive, antenna, heat spreader and electromagnetic interference (EMI) shield.

41. The die package as claimed in claim 39, wherein the components further comprise one or more integrated devices, each integrated device comprising any one or more of a group consisting of capacitor, resistor and inductor.

42. The die package as claimed in claim 25, further comprising a redistribution layer disposed on the connecting portions of the package-internal free-standing interconnect structures.

43. The die package as claimed in claim 25, further comprising a conductive layer disposed on the connecting portions of the package-internal free-standing interconnect structures, and a redistribution layer disposed on or above a surface of the package material facing away from the connecting portions of the package-internal free-standing interconnect structures.

44. The die package as claimed in claim 43, further comprising a third package-internal free-standing interconnect structure disposed at a first end of the die package, wherein the third package-internal free-standing interconnect structure extends from the conductive layer to the redistribution layer.

45. The die package as claimed in claim 44, wherein the third package-internal free-standing interconnect structure is further disposed at a second end of the die package, wherein the first end and the second end of the die package are opposing ends.

46. The die package as claimed in claim 42, further comprising a dielectric layer disposed on the redistribution layer.

47. The die package as claimed in claim 42, further comprising metallic interconnects disposed on the redistribution layer.

48. The die package as claimed in claim 47, wherein the metallic interconnects comprise solder bumps.

49-63. (canceled)
